(19) United States
(12) Patent Application Publication
(10) Pub. No.: US 2009/0194414 A1
(43) Pub. Date: Aug. 6, 2009

(54) MODIFIED SPUTTERING TARGET AND DEPOSITION COMPONENTS, METHODS OF PRODUCTION AND USES THEREOF

(76) Inventors: Ira G. Nolander, Spokane, WA (US); William B. Willett, Spokane, WA (US); Marc Ruggiero, Liberty Lake, WA (US)

Correspondence Address: HONEYWELL INTERNATIONAL INC.;PATENT SERVICES, 101 COLUMBIA ROAD, P O BOX 2245, MORRISTOWN, NJ, 07962-2245, US

(21) Appl. No.: 12/188,102

(22) Filed: Aug. 7, 2008

Related U.S. Application Data
(60) Provisional application No. 61/025,144, filed on Jan. 31, 2008.

(51) Int. Cl. C23C 14/34; C23C 14/56

(52) U.S. Cl. 204/298.13; 204/298.02; 29/746; 29/825

(57) ABSTRACT

Deposition apparatus are described herein that include at least one coil, at least one coil set, at least one coil-related apparatus, at least one target-related apparatus or a combination thereof, wherein the at least one coil, at least one coil set, at least one coil-related apparatus, at least one target-related apparatus or a combination thereof comprises a surface, and wherein at least part of the surface comprises a regular depth pattern. Methods of producing a coil, coil set or a coil-related apparatus, at least one target-related apparatus are also disclosed herein that comprise: providing at least one coil, at least one coil set, at least one coil-related apparatus, at least one target-related apparatus or a combination thereof, wherein the at least one coil, at least one coil set, at least one coil-related apparatus, at least one target-related apparatus or a combination thereof comprises a surface, providing a patterning tool; and utilizing the patterning tool to create a regular depth pattern in at least part of the surface.

### FIELD OF THE SUBJECT MATTER

The field of the subject matter is sputtering target and deposition components; including coils and related devices and apparatus that are pattern-modified and/or texture-modified in order to improve performance of the component and/or add lifetime to the component, among other benefits.

### BACKGROUND

Deposition methods are utilized for forming films of material across substrate surfaces. Deposition methods can be utilized in, for example, semiconductor fabrication processes to form layers ultimately utilized in fabrication of integrated circuitry structures and devices. Examples of contemplated deposition methods include chemical vapor deposition (CVD), atomic layer deposition (ALD), metalorganic chemical vapor deposition (MOCVD) and physical vapor deposition (PVD). PVD methodologies include sputtering processes.

Chamber system components may include target flanges, target sidewalls, shields, cover rings, coils, cups, pins and/or clamps. These components can be modified in a number of ways to improve their ability to function as particle traps and also reduce problems associated with particle formation. For example, U.S. patent application Ser. Nos. 10/614,806, 10/837,555, and 10/985,316, along with U.S. Provisional Application Ser. Nos. 60/477,810, 60/498,036 and 60/396,543, which are all commonly-owned by Honeywell International Inc. and incorporated herein by reference in their entirety, disclose forming traps for particle entrapment by forming a bent scroll pattern on one or more surfaces within a deposition chamber.

U.S. Pat. No. 5,391,275 to Mintz teaches a method of preparing a shield and/or clamping ring prior to use in a physical vapor deposition process, the shield and/or clamping ring is first bead blasted and then is treated in an ultrasonic cleaning chamber to remove loose particles. The component is then sputter etched or treated with a plasma. In Column 2, lines 31-37, Mintz states that “The bead blasting step makes the surface of the shield and/or clamping ring irregular. This enhances interface crack propagation of deposited material on a submicroscopic scale and hinders the flaking of deposited material. The surface irregularities force a fracture propagating along a plane of weakness to change direction or pass through a stronger region.”

U.S. Pat. No. 5,837,057 to Koyama reference discloses a film-forming apparatus that utilizes a separate particle prevention plate or plates to control particles within the chamber or apparatus. Koyama solves the particle problem by inserting plates inside the apparatus. Koyama does not treat the surface of already existing chamber or apparatus components to form the macro-scale trapping region. Koyama discloses forming projections having a “pitch”—which means that they are slanted.

One contemplated chamber component is a coil or coil set, such as those that are being produced by Honeywell Electronic Materials™, which are consumable products placed inside the sputtering chamber or ionized plasma apparatus that redirect sputtered atoms and/or molecules to form a more uniform film and/or layer on a substrate and/or suitable surface. For background purposes, the coil is present in these systems and/or deposition apparatus as an inductively coupling device to create a secondary plasma of sufficient density to ionize at least some of the metal atoms that are sputtered from the target. In an ionized metal plasma system, the primary plasma forms and is generally confined near the target by the magnetron, and subsequently gives rise to atoms, such as Ti atoms, being ejected from the target surface. The secondary plasma formed by the coil system produces Ti, Cu & Ta ions (depending on material being sputtered). These metal ions are then attracted to the wafer by the field in the sheath that forms at the substrate (wafer) surface. As used herein, the term “sheath” means a boundary layer that forms between a plasma and any solid surface. This field can be controlled by applying a bias voltage to the wafer and/or substrate.

Conventional coils are suspended on ceramic electrical insulators to prevent the coil potential from shorting to the processing chamber shields that are attached to the process chamber walls, and are thus, at ground potential. The metal plasma will coat the ceramic insulators and form a short circuit. Shields, formed in the shape of cups, are placed around the ceramic to provide an optically dense path from the plasma to the ceramic that would prevent the deposition of metals on the ceramics. Typically, a small cup-like shield that encompasses the ceramic is attached to the coil and a larger cup-like shield is attached to the smaller cup-like shield such that the cups are electrically isolated from each other but collectively work to shield the ceramic. Under heat stress, the coil expands and reduces the nominal gap between the backside of the coil and the edge of the outside cup-like shield, creating a short circuit and interrupting the deposition process on the substrate.

In addition to those problems and potential defects described above, particle generation during physical vapor deposition (PVD) is one of the most detrimental factors that reduce the yield of functional chips in microelectronic device fabrication. In PVD systems, particles are mainly generated when deposits build up on surrounding chamber components and stress induced cracking occurs, particularly on the coil that is being used in the ionized metal plasma (IMP) and self ionized plasma (SIP) sputtering systems. Deposition mainly occurs on top of these coils.

Conventional coils and coils sets can be difficult to manufacture because of the size of the metal or metal alloy rod being used. Therefore, it would be desirable to develop better shaped and sized coils for utilization with a deposition apparatus, a sputtering chamber system and/or ionized plasma deposition system without causing shorts, interruptions to the deposition process or inappropriate metal deposition. It would also be desirable to ensure that those new coils and coil sets will have a similar lifetime relative to the target being used, because decreasing the difference in lifetime between the coils, coil sets and targets would, at the very least, decrease the number of times the apparatus or systems have to be shut down to replace coils before replacing both the coil and target.

It would also be desirable to add texture to a component, including a coil or coil set, that is more uniform, cleaner, more robust, produces a component that meets roughness requirements, while maintaining the ability to refurbish. U.S. Pat. No. 6,812,471 discloses modified coils and coil sets and uses a beam of electromagnetic energy to apply the texture. WO 2007/030824 A2 utilizes flow forming with mandrel to add texture. Neither of these approaches, however, accomplish the previously-mentioned goals. In addition, contemplated modified components and coils are not expected to have the same flaking issues associated with other methods of surface texturing.

Based on the conventional systems and current state of the art, it would be desirable to develop and utilize a deposition apparatus and sputtering chamber system that will maximize uniformity of the coating, film or deposition on a surface and/or substrate by utilizing a coil or coil set that is more uniform, cleaner and more robust, while also maintaining roughness requirements and maintaining the ability to refurbish.

### BRIEF DESCRIPTION OF THE FIGURES

FIG. 1 is a representation of a contemplated pattern.

FIG. 2 shows an actual surface showing the pattern.

FIGS. 3A and 3B show a contemplated knurling tool from both a side (3A) and bottom (3B) perspective.

### SUMMARY

Deposition apparatus are described herein that include at least one coil, at least one coil set, at least one coil-related apparatus, at least one target-related apparatus or a combination thereof, wherein the at least one coil, at least one coil set, at least one coil-related apparatus, at least one target-related apparatus or a combination thereof comprises a surface, and wherein at least part of the surface comprises a regular depth pattern.

Methods of producing a coil, coil set, at least one target-related apparatus or a coil-related apparatus are also disclosed herein that comprise: providing at least one coil, at least one coil set, at least one coil-related apparatus, at least one target-related apparatus or a combination thereof, wherein the at least one coil, at least one coil set, at least one coil-related apparatus, at least one target-related apparatus or a combination thereof comprises a surface, providing a patterning tool; and utilizing the patterning tool to create a regular depth pattern in at least part of the surface.

### DETAILED DESCRIPTION

Better shaped and sized coils have also been developed that are ultimately more cost efficient coils and coil sets for utilization with a deposition apparatus, a sputtering chamber system and/or ionized plasma deposition system without causing shorts, interruptions to the deposition process or inappropriate metal deposition. Contemplated deposition apparatus and sputtering chamber system has been developed and utilized that maximizes uniformity of the coating, film or deposition on a surface and/or substrate by utilizing a coil or coil set that is more uniform, cleaner and more robust, while also maintaining roughness requirements and maintaining the ability to refurbish.

These new coils and coil sets have a similar lifetime relative to the target being used, because decreasing the difference in lifetime between the coils, coil sets and targets decrease the number of times the apparatus or systems have to be shut down to replace coils before replacing both the coil and target.

Specifically, a contemplated deposition apparatus comprises at least one coil, at least one coil set, at least one related component or a combination thereof that comprises a specifically designed and planned texture geometry so as to accomplish all of the design and performance goals described herein. This specifically designed and planned texture geometry corrects the problems with techniques involving roughening, as described earlier. Contemplated deposition apparatus comprise at least one coil, at least one coil set, at least one coil-related apparatus, at least one target-related apparatus or a combination thereof, wherein the at least one coil, at least one coil set, at least one coil-related apparatus, at least one target-related apparatus or a combination thereof comprises a surface, and wherein at least part of the surface comprises a regular depth pattern.

Methods of producing a coil, coil set or a coil-related and/or target-related apparatus are also disclosed herein that comprise: providing at least one coil, at least one coil set, at least one coil-related apparatus, at least one target-related apparatus, or a combination thereof, wherein the at least one coil, at least one coil set, at least one coil-related apparatus, at least one target-related apparatus or a combination thereof comprises a surface, providing a patterning tool; and utilizing the patterning tool to create a regular depth pattern in at least part of the surface. As used herein, coil-related and target-related apparatus include target flanges, target sidewalls, shields, cover rings, cups, pins and/or clamps.

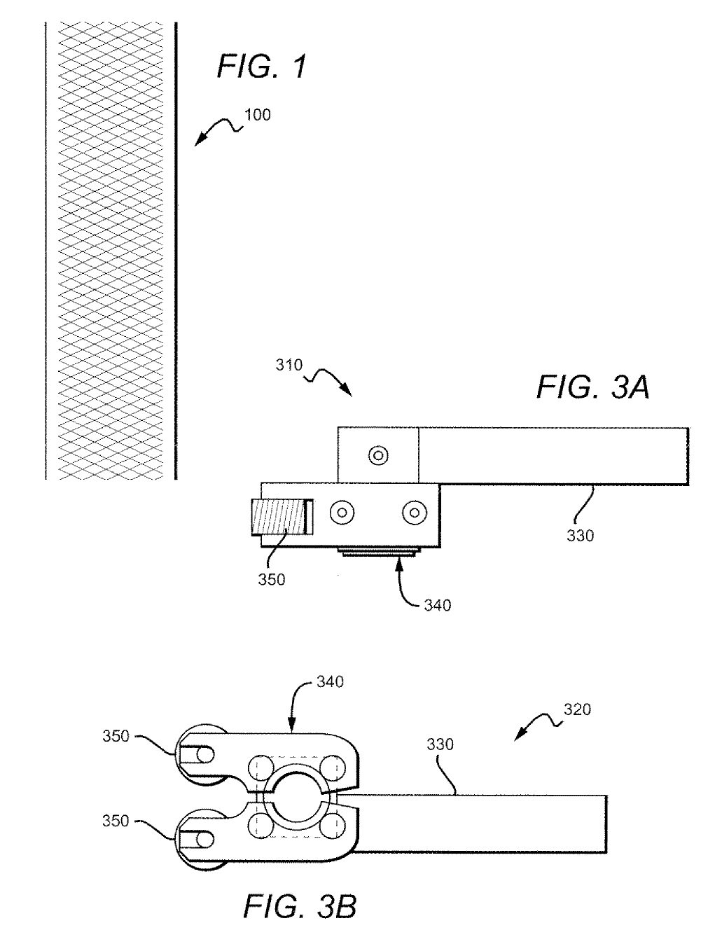

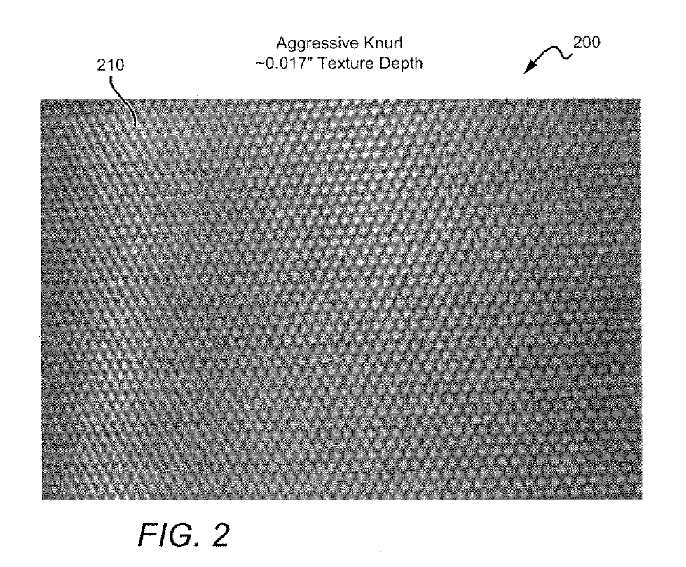

In contemplated embodiments, controlled and specific texture geometries or structured surfaces are applied to components without the use of a roughening technique, such as bead blasting, and without following with a random etching step. Contemplated texture geometries include specific and targeted patterns, including diamond or crosshatch patterns, such as the one shown in FIG. 1, which is a representation of a contemplated pattern 100, and FIG. 2, which is an actual surface 200 showing the pattern 210.

Any suitable tool or subtractive method may be utilized to form the unique, specific and targeted patterns disclosed herein having regular depth patterns, including mechanical tools. A suitable tool comprises any mechanically patterning tool that achieves desired roughness contemplated and claimed. FIG. 3 shows a contemplated patterning tool—in this case a knurling tool—from both a side 310 and bottom 320 perspective. The handle 330 and cutting mechanism 340 is shown, along with the cutting blades 350. It should be understood that the processes of bead blasting or random etching will not form the specific patterns disclosed herein.

Contemplated patterning tools and processes result in component texture geometries having an average depth pattern that is at least an average of 0.350 mm deep. In some embodiments, contemplated component texture geometries are at least an average of 0.380 mm deep. In other embodiments, contemplated component texture geometries having an average depth pattern that is at least an average of 0.400 mm deep. In yet other embodiments, contemplated component texture geometries having an average depth pattern that is at least an average 0.500 mm deep. In some embodiments, the contemplated component texture geometries having an average depth pattern that is less than an average of 1.143 mm deep. As used herein, the phrase “at least an average” with respect to the depth of the texture geometry means that the average depth over the length of the texture geometry is at least as deep as specified. Some areas may be 0.450 mm and some areas in the same geometry may be 0.520 mm deep, but the average is within the range specified herein.

These regular depth patterns, texture geometries and/or structured surfaces, formed by a knurling tool and process or similar device/method, are tightly controlled, resulting in a cleaner, more consistent surface texture. These components and coils can be refurbished after use, unlike refurbishment of coils using alternative surface texture that lead to jagged edges which may cause arcing or flaking during use.

Components contemplated herein may generally comprise any material that can be reliably formed into a deposition system component. Materials that are contemplated to make suitable components are metals, metal alloys, hard mask materials and any other suitable material.

As used herein, the term “metal” means those elements that are in the d-block and f-block of the Periodic Chart of the Elements, along with those elements that have metal-like properties, such as silicon and germanium. As used herein, the phrase “d-block” means those elements that have electrons filling the 3d, 4d, 5d, and 6d orbitals surrounding the nucleus of the element. As used herein, the phrase “f-block” means those elements that have electrons filling the 4f and 5f orbitals surrounding the nucleus of the element, including the lanthanides and the actinides. Some contemplated metals include tantalum, cobalt, copper, indium, gallium, selenium, nickel, iron, zinc, aluminum and aluminum-based materials, tin, gold, silver, or a combination thereof. Other contemplated metals include copper, aluminum, cobalt, magnesium, manganese, iron or a combination thereof.

The term “metal” also includes alloys. Alloys contemplated herein comprise gold, antimony, aluminum, copper, nickel, indium, cobalt, vanadium, iron, titanium, zirconium, silver, tin, zinc, rhenium, and combinations thereof. Specific alloys include gold antimony, gold arsenic, gold boron, gold copper, gold germanium, gold nickel, gold nickel indium, gold palladium, gold phosphorus, gold silicon, gold silver platinum, gold tantalum, gold tin, gold zinc, palladium lithium, palladium manganese, silver copper, silver gallium, silver gold, aluminum copper, aluminum silicon, aluminum silicon copper, aluminum titanium, chromium copper, and/or combinations thereof. In some embodiments, contemplated materials include those materials disclosed in U.S. Pat. No. 6,331,233, which is commonly-owned by Honeywell International Inc., and which is incorporated herein in its entirety by reference.

Metals and alloys contemplated herein may also comprise other metals in smaller amounts. These metals may be naturally-occurring in certain component formations or may be added during the target production. It is contemplated that these metals either provide no change to the overall component properties or are designed to improve the component properties.

Thus, specific embodiments and applications of methods of manufacturing deposition system components and related apparatus have been disclosed. It should be apparent, however, to those skilled in the art that many more modifications besides those already described are possible without departing from the inventive concepts herein. The inventive subject matter, therefore, is not to be restricted except in the spirit of the disclosure herein. Moreover, in interpreting the disclosure, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

We claim:

1. A deposition apparatus, comprising:
at least one coil, at least one coil set, at least one coil-related apparatus, at least one target-related apparatus or a combination thereof, wherein the at least one coil, at least one coil set, at least one coil-related apparatus, at least one target-related apparatus or a combination thereof comprises a surface, and wherein at least part of the surface comprises a regular depth pattern.

2. The deposition apparatus of claim 1, wherein the at least one coil, at least one coil set, at least one coil-related apparatus, at least one target-related apparatus or a combination thereof comprises at least one metal.

3. The deposition apparatus of claim 1, wherein the regular depth pattern comprises a diamond pattern, a crosshatch pattern or a combination thereof.

4. The deposition apparatus of claim 1, wherein the average depth of the regular depth pattern is at least 0.350 mm.

5. The deposition apparatus of claim 1, wherein the average depth of the regular depth pattern is at least 0.400 mm.

6. The deposition apparatus of claim 1, wherein the average depth of the regular depth pattern is less than an average of 1.143 mm.

7. The deposition apparatus of claim 1, wherein the at least one coil-related apparatus or the at least one target-related apparatus comprises a target flange, a target sidewall, a shield, a cover ring, a cup, a pin, a clamp or a combination thereof.

8. A method of producing a coil, coil set or a coil-related apparatus, comprising:
providing at least one coil, at least one coil set, at least one coil-related apparatus, or a combination thereof, wherein the at least one coil, at least one coil set, at least one coil-related apparatus or a combination thereof comprises a surface,
providing a patterning tool; and
utilizing the patterning tool to create a regular depth pattern in at least part of the surface.

9. The method of claim 8, wherein the patterning tool comprises of any mechanically patterning tool

10. The method of claim 8, wherein the regular depth pattern comprises a diamond pattern, a crosshatch pattern or a combination thereof.

11. The method of claim 8, wherein the average depth of the regular depth pattern is at least 0.350 mm.

12. The method of claim 8, wherein the average depth of the regular depth pattern is at least 0.400 mm.

13. The method of claim 8, wherein the average depth of the regular depth pattern is less than an average of 1.143 mm.
